(19) United States
(12) Patent Application Publication
(10) Pub. No.: US 2020/0013473 A1
(43) Pub. Date: Jan. 9, 2020

(54) SHIFT REGISTER, METHOD FOR DRIVING THE SAME, GATE INTEGRATED DRIVER CIRCUIT, AND DISPLAY DEVICE

(71) Applicant: BOE TECHNOLOGY GROUP CO., LTD., Beijing (CN)

(72) Inventors: Minghua Xuan, Beijing (CN); Shengji Yang, Beijing (CN); Li Xiao, Beijing (CN); Jie Fu, Beijing (CN); Lei Wang, Beijing (CN); Pengcheng Lu, Beijing (CN); Xiaochuan Chen, Beijing (CN)

(21) Appl. No.: 15/775,638

(22) PCT Filed: Nov. 17, 2017
(86) PCT No.: PCT/CN2017/111573

§ 371 Date: May 11, 2018

(30) Foreign Application Priority Data
May 9, 2017 (CN) 201710322066.6

(51) Int. Cl. G11C 19/28; G09G 3/36

(52) U.S. Cl. CPC G11C 19/28; G09G 2310/0286; G09G 3/3677

(57) ABSTRACT

This disclosure discloses a shift register, a method for driving the same, a gate integrated driver circuit, and a display device, and the shift register includes an input control circuit, a first output control circuit, a pull-up control circuit, a first pull-down control circuit, and a second output control circuit, where the first output control circuit and the second output control circuit operate in cooperation to provide a high-level signal and a low-level signal respectively, and the pull-up control circuit and the second output control circuit operate in cooperation to reset a signal output terminal.

This application claims the benefit of Chinese Patent Application No. 201710322066.6, filed with the Chinese Patent Office on May 9, 2017, and entitled “A shift register, a method for driving the same, a gate integrated driver circuit, and a display device”, which is hereby incorporated by reference in its entirety.

### FIELD

The present disclosure relates to the field of display technologies, and particularly to a shift register, a method for driving the same, a gate integrated driver circuit, and a display device.

### BACKGROUND

A Gate on Array (GOA) is a technology in which a gate integrated driver circuit is integrated on a TFT substrate; and the gate integrated driver circuit provides gates of respective switch transistors in a pixel area with a gate scan signal to switch the respective switch transistors in rows, so that a data signal is input to pixel elements.

Typically, in order to enable the GOA to provide a display panel with a stable gate scan signal, a shift register, which is a component of the gate integrated driver circuit, generally includes fifteen switch transistors and at least one capacitor, but this design tends to make the circuit complicated in structure, and in a large area, thus discouraging a design with a narrow bezel. Furthermore in the shift register, some switch transistor keeps on operating, so that threshold voltage of the switch transistor may drift, but also the service lifetime of the switch transistor may be shortened, thus hindering the switch transistor from operating normally.

### SUMMARY

Embodiments of this disclosure provide a shift register, a method for driving the same, a gate integrated driver circuit, and a display device so as to simplify the structure of the shift register, and also enable each switch transistor to operate intermittently, so that the service lifetime of the switch transistor can be extended while the switch transistor is operating normally.

An embodiment of this disclosure provides a shift register including: an input control circuit, connected to a signal input terminal, a first clock signal terminal, and a first node respectively, configured to output a signal input at the signal input terminal to the first node under the control of the first clock signal terminal; a first output control circuit, connected to the first node, a second clock signal terminal, and a signal output terminal respectively, configured to output a clock signal input at the second clock signal terminal to the signal output terminal under the control of the first node; a pull-up control circuit, connected to the first clock signal terminal, a second node, and a first reference signal terminal respectively, configured to output a first reference signal input at the first reference signal terminal to the second node under the control of the first clock signal terminal; a pull-down control circuit, connected to the first node, the first clock signal terminal, and the second node respectively, configured to output a clock signal input at the first clock signal terminal to the second node under the control of the first node; and a second output control circuit, connected to the second node, a second reference signal terminal, and the signal output terminal respectively, configured to output a second reference signal input at the second reference signal terminal to the signal output terminal under the control of the second node.

In some possible implementation, in the shift register above according to the embodiment of this disclosure, the input control circuit includes a first switch transistor, wherein: the first switch transistor has a control electrode connected with the first clock signal terminal, a first electrode connected with the signal input terminal, and a second electrode connected with the first node.

In some possible implementation, in the shift register above according to the embodiment of this disclosure, the first output control circuit includes a second switch transistor and a first capacitor, wherein: the second switch transistor includes a control electrode connected with the first node, a first electrode connected with the second clock signal terminal, and a second electrode connected with the signal output terminal; and the first capacitor is connected between the first node and the signal output terminal.

In some possible implementation, in the shift register above according to the embodiment of this disclosure, the pull-up control circuit includes a third switch transistor, wherein: the third switch transistor includes a control electrode connected with the first clock signal terminal, a first electrode connected with the first reference signal terminal, and a second electrode connected with the second node.

In some possible implementation, in the shift register above according to the embodiment of this disclosure, the second output control circuit includes a fourth switch transistor and a second capacitor, wherein: the fourth switch transistor includes a control electrode connected with the second node, a first electrode connected with the second reference signal terminal, and a second electrode connected with the signal output terminal; and the second capacitor is connected between the second node and the second reference signal terminal.

In some possible implementation, in the shift register above according to the embodiment of this disclosure, the first pull-down control circuit includes a fifth switch transistor, wherein: the fifth switch transistor includes a control electrode connected with the first node, a first electrode connected with the first clock signal terminal, and a second electrode connected with the second node.

In some possible implementation, in the shift register above according to the embodiment of this disclosure, the shift register further includes a second pull-down control circuit, connected to the first node, the second node, the second clock signal terminal, and the second reference signal terminal respectively, configured to output the second reference signal input at the second reference signal terminal to the first node under a joint control of the second node, and the clock signal input at the second clock signal terminal.

In some possible implementation, in the shift register above according to the embodiment of this disclosure, the second pull-down control circuit includes a sixth switch transistor and a seventh switch transistor, wherein: the sixth switch transistor includes a control electrode connected with the second node, a first electrode connected with the second reference signal terminal, and a second electrode connected with a third node; and the seventh switch transistor includes a control electrode connected with the second clock signal terminal, a first electrode connected with the third node, and a second electrode connected with the first node.

An embodiment of this disclosure further provides a gate integrated driver circuit including a plurality of cascaded shift registers according to the embodiment of this disclosure, wherein: the signal input terminal of a first level shift register of the plurality of shift registers is connected with a frame start signal terminal; and the signal output terminal of each of other level shift registers of the plurality of shift registers than a last level shift register of the plurality of shift registers is connected with a signal input terminal of an immediately succeeding level shift register of the each of other shift registers.

An embodiment of this disclosure further provides a display device including the gate integrated driver circuit above according to the embodiment of this disclosure.

An embodiment of this disclosure further provides a method for driving the shift register above according to the embodiment of this disclosure, the method including: providing, by the first clock signal terminal, the input control circuit, the pull-up control circuit, and the first pull-down control circuit respectively with a first level signal, and providing, by the signal input terminal, the input control circuit with the first level signal, so that a second level signal at the second clock signal terminal, and the second level signal at the second reference signal terminal are output to the signal output terminal; providing, by the first clock signal terminal, the input control circuit, the pull-up control circuit, and the first pull-down control circuit respectively with the second level signal, and providing, by the signal input terminal, the input control circuit with the second level signal, so that the first level signal at the second clock signal terminal is output to the signal output terminal; providing, by the first clock signal terminal, the input control circuit, the pull-up control circuit, and the first pull-down control circuit respectively with the first level signal, and providing, by the signal input terminal, the input control circuit with the second level signal, so that the second level signal at the second reference signal terminal is output to the signal output terminal; and providing, by the first clock signal terminal, the input control circuit, the pull-up control circuit, and the first pull-down control circuit respectively with the second level signal, and providing, by the signal input terminal, the input control circuit with the second level signal, so that the second level signal at the second reference signal terminal is output to the signal output terminal.

In some possible implementation, in the driving method above according to the embodiment of this disclosure, when the first clock signal terminal provides the input control circuit, the pull-up control circuit, and the first pull-down control circuit respectively with the second level signal, and the signal input terminal provides the input control circuit with the second level signal, so that the second level signal terminal at the second reference signal terminal is output to the signal output terminal, the method further includes: providing, by the second clock signal terminal, the second pull-down control circuit with the first level signal, so that the second reference signal at the second reference terminal is output to the first node.

### BRIEF DESCRIPTION OF THE DRAWINGS

FIG. 1 and FIG. 2 are schematic structural diagrams respectively of a shift register according to an embodiment of this disclosure.

FIG. 3a is a first schematic structural diagram of the shift register as illustrated in FIG. 2 according to an embodiment of this disclosure in details.

FIG. 3b is a second schematic structural diagram of the shift register as illustrated in FIG. 2 according to an embodiment of this disclosure in details.

FIG. 4 is an input-output timing diagram of a shift register according to an embodiment of this disclosure.

FIG. 5a to FIG. 5d are schematic diagrams respectively of operating states of respective switch transistors in the shift register according to the embodiment of this disclosure in respective periods of time.

FIG. 6 is a schematic structural diagram of a gate integrated driver circuit according to an embodiment of this disclosure.

### DETAILED DESCRIPTION OF THE EMBODIMENTS

Implementations of a shift register, a method for driving the same, a gate integrated driver circuit, and a display device according to embodiments of the disclosure will be described below in details with reference to the drawings. It shall be noted that the embodiments to be described are only a part but not all of the embodiments of this disclosure. Based upon the embodiments here of this disclosure, all the other embodiments which can occur to those ordinarily skilled in the art without any inventive effort shall fall into the scope of this disclosure as claimed.

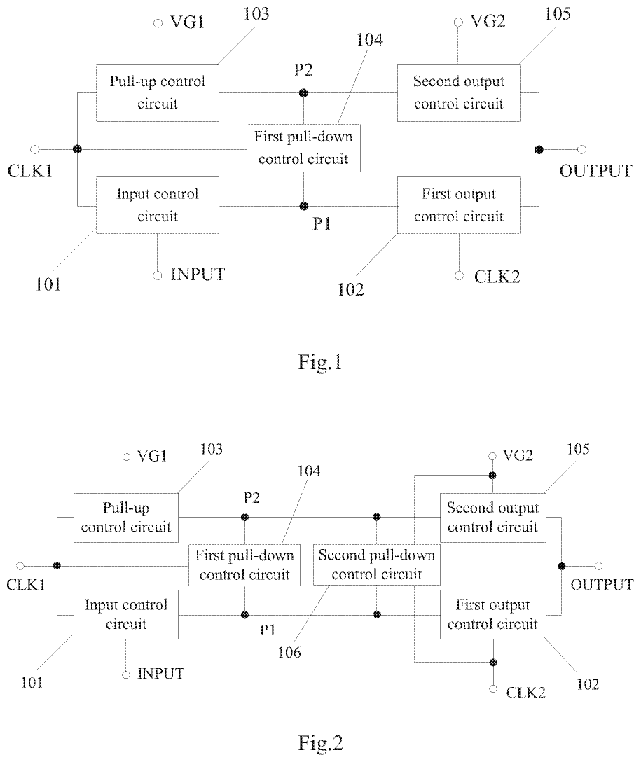

An embodiment of this disclosure provides a shift register as illustrated in FIG. 1 and FIG. 2, which can include: an input control circuit 101, connected to a signal input terminal INPUT, a first clock signal terminal CLK1, and a first node P1 respectively, configured to output a signal input at the signal input terminal INPUT to the first node P1 under the control of the first clock signal terminal CLK1; a first output control circuit 102, connected to the first node P1, a second clock signal terminal CLK2, and a signal output terminal OUTPUT respectively, configured to output a clock signal input at the second clock signal terminal CLK2 to the signal output terminal OUTPUT under the control of the first node P1; a pull-up control circuit 103, connected to the first clock signal terminal CLK1, a second node P2, and a first reference signal terminal VG1 respectively, configured to output a first reference signal input at the first reference signal terminal VG1 to the second node P2 under the control of the first clock signal terminal CLK1; a pull-down control circuit 104, connected to the first node P1, the first clock signal terminal CLK1, and the second node P2 respectively, configured to output a clock signal input at the first clock signal terminal CLK1 to the second node P2 under the control of the first node P1; and a second output control circuit 105, connected to the second node P2, a second reference signal terminal VG2, and the signal output terminal OUTPUT respectively, configured to output a second reference signal input at the second reference signal terminal VG2 to the signal output terminal OUTPUT under the control of the second node P2.

Optionally the first clock signal terminal CLK1 and the second clock signal terminal CLK2 are configured respectively to provide periodical clock signals with a phase difference of 90°, that is, when the clock signal input at the first clock signal terminal CLK1 is a high-level signal, the clock signal input at the second clock signal terminal CLK2 is a low-level signal; or when the clock signal input at the first clock signal terminal CLK1 is a low-level signal, the clock signal input at the second clock signal terminal CLK2 is a high-level signal. Furthermore in an optional implementation, an active pulse signal at the signal input terminal is a high-level signal, the first reference signal at the first reference signal terminal VG1 is a high-level signal, and the second reference signal at the second reference signal terminal VG2 is a low-level signal; or an active pulse signal at the signal input terminal is a low-level signal, the first reference signal at the first reference signal terminal VG1 is a low-level signal, and the second reference signal at the second reference signal terminal VG2 is a high-level signal.

In the shift register above according to the embodiment of this disclosure, the first output control circuit 102 and the second output control circuit 105 can be arranged respectively to provide a high-level signal and a low-level signal, and to output a stable low-level signal without any interference from another signal. Also the first output control circuit 102 and the second output control circuit 105 can operate intermittently to thereby extend the service lifetime of the shift register. Furthermore the pull-up control circuit 103 and the second output control circuit 105 can operate in cooperation to thereby function as a reset circuit for resetting the signal output terminal OUTPUT, so a reset circuit can be dispensed with to thereby greatly simplify the structure of the shift register so as to facilitate a design of a display device with a narrow bezel.

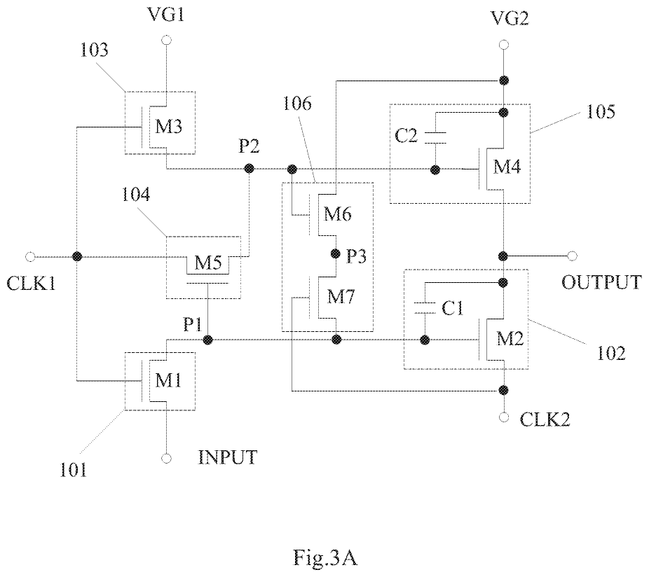

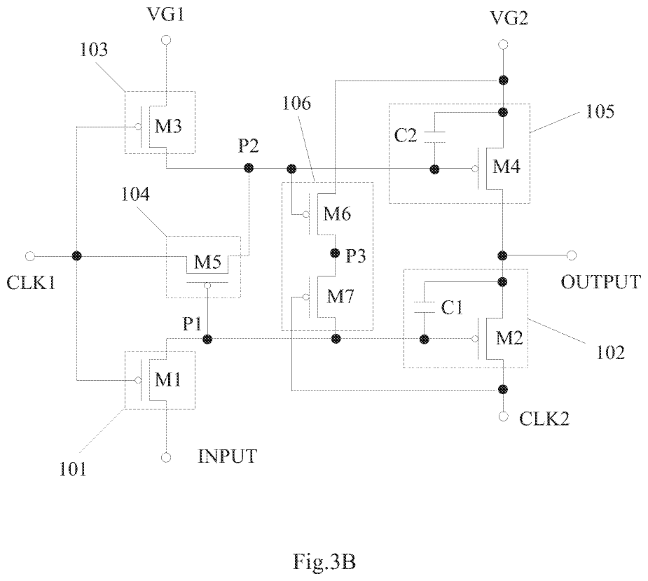

In an optional implementation, in order to provide the first node P1 with the signal input at the signal input terminal INPUT, in the shift register above according to the embodiment of this disclosure, as illustrated in FIG. 3a and FIG. 3b, the input control circuit 101 can include a first switch transistor M1.

The first switch transistor M1 has a control electrode connected with the first clock signal terminal CLK1, a first electrode connected with the signal input terminal INPUT, and a second electrode connected with the first node P1.

Optionally the first switch transistor M1 outputs the signal input at the signal input terminal INPUT to the first node P1 under the control of an active clock signal input at the first clock signal terminal CLK1.

Optionally as illustrated in FIG. 3b, the first switch transistor M1 can be a P-type switch transistor, or as illustrated in FIG. 3a, the first switch transistor M1 can be an N-type switch transistor, although the embodiment of this disclosure will not be limited thereto. When the first switch transistor M1 is a P-type switch transistor, the active clock signal input at the first clock signal terminal CLK1 is a low-level signal; and when the first switch transistor M1 is an N-type switch transistor, the active clock signal input at the first clock signal terminal CLK1 is a high-level signal.

The optional structure of the input control circuit 101 has been described above merely by way of an example, and in an optional implementation, the optional structure of the input control circuit 101 will not be limited to the structure above according to the embodiment of this disclosure, but can alternatively be another structure known to those skilled in the art, although the embodiment of this disclosure will not be limited thereto.

In an optional implementation, in order to enable the signal output terminal OUTPUT of the shift register to output a high-level signal or a low-levels signal, in the shift register above according to the embodiment of this disclosure, as illustrated in FIG. 3a and FIG. 3b, the first output control circuit 102 can include a second switch transistor M2 and a first capacitor C1.

The second switch transistor M2 has a control electrode connected with the first node P1, a first electrode connected with the second clock signal terminal CLK2, and a second electrode connected with the signal output terminal OUTPUT.

The first capacitor C1 is connected between the first node P1 and the signal output terminal OUTPUT.

Optionally the second switch transistor M2 outputs the clock signal input at the second clock signal terminal CLK2 to the signal output terminal OUTPUT under the control of the signal at the first node P1.

Optionally as illustrated in FIG. 3b, the second switch transistor M2 can be a P-type switch transistor; or as illustrated in FIG. 3a, the second switch transistor M2 can be an N-type switch transistor, although the embodiment of this disclosure will not be limited thereto. When the second switch transistor M2 is a P-type switch transistor, the signal, at the first node P1, switching on the second switch transistor M2 is a low-level signal; and when the second switch transistor M2 is an N-type switch transistor, the signal, at the first node P1, switching on the second switch transistor M2 is a high-level signal.

The optional structure of the first output control circuit 102 has been described above merely by way of an example, and in an optional implementation, the optional structure of the first output control circuit 102 will not be limited to the structure above according to the embodiment of this disclosure, but can alternatively be another structure known to those skilled in the art, although the embodiment of this disclosure will not be limited thereto.

In an optional implementation, in order to control the level at the second node p2 to thereby further control the second output control circuit 105 to be switched on so as to control the level output at the signal output terminal OUTPUT, in the shift register above according to the embodiment of this disclosure, as illustrated in FIG. 3a and FIG. 3b, the pull-up control circuit 103 can include a third switch transistor M3.

The third switch transistor M3 has a control electrode connected with the first clock signal terminal CLK1, a first electrode connected with the first reference signal terminal VG1, and a second electrode connected with the second node P2.

Optionally the third switch transistor M3 outputs the first reference signal input at the first reference signal terminal VG1 to the second node P2 under the control of the active clock signal input at the first clock signal terminal CLK1.

Optionally as illustrated in FIG. 3b, the third switch transistor M3 can be a P-type switch transistor, or as illustrated in FIG. 3a, the third switch transistor M3 can be an N-type switch transistor, although the embodiment of this disclosure will not be limited thereto. When the third switch transistor M3 is a P-type switch transistor, the active clock signal input at the first clock signal terminal CLK1 is a low-level signal; and when the third switch transistor M3 is an N-type switch transistor, the active clock signal input at the first clock signal terminal CLK1 is a high-level signal.

The optional structure of the third pull-up control circuit 103 has been described above merely by way of an example, and in an optional implementation, the particular structure of the third pull-up control circuit 103 will not be limited to the structure above according to the embodiment of this disclosure, but can alternatively be another structure known to those skilled in the art, although the embodiment of this disclosure will not be limited thereto.

In an optional implementation, in order to enable the signal output terminal OUTPUT of the shift register to output a high-level signal or a low-level signal, in the shift register above according to the embodiment of this disclosure, as illustrated in FIG. 3a and FIG. 3b, the second output control circuit 105 can include a fourth switch transistor M4 and a second capacitor C2.

The fourth switch transistor M4 has a control electrode M4 connected with the second node P2, a first electrode connected with the second reference signal terminal VG2, and a second electrode connected with the signal output terminal OUTPUT.

The second capacitor C2 is connected between the second node P2 and the second reference signal terminal VG2.

Optionally the fourth switch transistor M4 outputs the second reference signal input at the second reference signal terminal VG2 to the signal output terminal OUTPUT under the control of the second node P2.

Optionally as illustrated in FIG. 3b, the fourth switch transistor M4 can be a P-type switch transistor; or as illustrated in FIG. 3a, the fourth switch transistor M4 can be an N-type switch transistor, although the embodiment of this disclosure will not be limited thereto. When the fourth switch transistor M4 is a P-type switch transistor, the level of the signal, at the second node P2, switching on the fourth switch transistor M4 is a low level; and when the fourth switch transistor M4 is an N-type switch transistor, the level of the signal, at the second node P2, switching on the fourth switch transistor M4 is a high level.

Furthermore the third switch transistor M3 is of the same transistor type as the fourth switch transistor M4, and both of them can be P-type switch transistors, or can be N-type switch transistors. When both the third switch transistor M3 and the fourth switch transistor M4 are P-type switch transistors, the active clock signal input at the first clock signal terminal CLK1 is a low-level signal, and the first reference signal input at the first reference signal terminal VG1 is also a low-level signal, so that the level at the second node P2 is a low level; and at this time, the fourth switch transistor M4 is switched on under the control of the low level at the second node P2, and the second reference signal input at the second reference signal terminal VG2 is a high-level signal, and transmitted to the signal output terminal OUTPUT. When both the third switch transistor M3 and the fourth switch transistor M4 are N-type switch transistors, the active clock signal input at the first clock signal terminal CLK1 is a high-level signal, and the first reference signal input at the first reference signal terminal VG1 is also a high-level signal, so that the level at the second node P2 is a high level; and at this time, the fourth switch transistor M4 is switched on under the control of the high level at the second node P2, and the second reference signal input at the second reference signal terminal VG2 is a low-level signal, and transmitted to the signal output terminal OUTPUT.

The optional structure of the second output control circuit 105 has been described above merely by way of an example, and in an optional implementation, the optional structure of the second output control circuit 105 will not be limited to the structure above according to the embodiment of this disclosure, but can alternatively be another structure known to those skilled in the art, although the embodiment of this disclosure will not be limited thereto.

In an optional implementation, in order to control the level at the second node P2, in the shift register above according to the embodiment of this disclosure, as illustrated in FIG. 3a and FIG. 3b, the first pull-down control circuit 104 can include a fifth switch transistor M5.

The fifth switch transistor M5 has a control electrode connected with the first node P1, a first electrode connected with the first clock signal terminal CLK1, and a second electrode connected with the second node P2.

Optionally the fifth switch transistor M5 outputs the clock signal input at the first clock signal terminal CLK1 to the second node P2 under the control of the first node P1.

Optionally as illustrated in FIG. 3b, the fifth switch transistor M5 can be a P-type switch transistor, or as illustrated in FIG. 3a, the fifth switch transistor M5 can be an N-type switch transistor, although the embodiment of this disclosure will not be limited thereto. When the fifth switch transistor M5 is a P-type switch transistor, the level of the signal, at the first node P1, switching on the fifth switch transistor M5 is a low level; and when the fifth switch transistor M5 is an N-type switch transistor, the level of the signal, at the first node P1, switching on the fifth switch transistor M5 is a high level.

The optional structure of the first pull-down control circuit 104 has been described above merely by way of an example, and in an optional implementation, the optional structure of the first pull-down control circuit 104 will not be limited to the structure above according to the embodiment of this disclosure, but can alternatively be another structure known to those skilled in the art, although the embodiment of this disclosure will not be limited thereto.

In an optional implementation, in order to avoid the second output control circuit 105 outputting a signal from being subjected to interference from a signal of the output control circuit 102, in the shift register above according to the embodiment of this disclosure, as illustrated in FIG. 2, the shift register can further include a second pull-down control circuit 106, connected to the first node P1, the second node P2, the second clock signal terminal CLK2, and the second reference signal terminal VG2 respectively, configured to output the second reference signal input at the second reference signal terminal VG2 to the first node P1 under the joint control of the second node P2, and the clock signal input at the second clock signal terminal CLK2.

Optionally in the shift register above according to the embodiment of this disclosure, as illustrated in FIG. 3a and FIG. 3b, the second pull-down control circuit 106 can include a sixth switch transistor M6 and a seventh switch transistor M7.

The sixth switch transistor M6 has a control electrode connected with the second node P2, a first electrode connected with the second reference signal terminal VG2, and a second electrode connected with a third node P3.

The seventh switch transistor M7 has a control electrode connected with the second clock signal terminal CLK2, a first electrode connected with the third node P3, and a second electrode connected with the first node P1.

Furthermore the sixth switch transistor M6 outputs the second reference signal input at the second reference signal terminal VG2 to the third node P3 under the control of the second node P2; and the seventh switch transistor M7 outputs a level signal at the third node P3 to the first node P1 under the control of the active clock signal input at the second clock signal terminal CLK2.

Furthermore as illustrated in FIG. 3b, the sixth switch transistor M6 and the seventh switch transistor M7 can be P-type switch transistors; or as illustrated in FIG. 3a, the sixth switch transistor M6 and the seventh switch transistor M7 can be N-type switch transistors, although the embodiment of this disclosure will not be limited thereto. When both the sixth switch transistor M6 and the seventh switch transistor M7 are P-type switch transistors, the level of the signal, at the second node P2, switching the sixth switch transistor M6 is a low level, and the level of the active clock signal, input at the second clock signal terminal CLK2, switching on the seventh switch transistor M7 is a low-level signal; and when both the sixth switch transistor M6 and the seventh switch transistor M7 are N-type switch transistors, the level of the signal, at the second node P2, switching the sixth switch transistor M6 is a high level, and the level of the active clock signal, input at the second clock signal terminal CLK2, switching on the seventh switch transistor M7 is a high-level signal.

The optional structure of the second pull-down control circuit 106 has been described above merely by way of an example, and in an optional implementation, the optional structure of the second pull-down control circuit 106 will not be limited to the structure above according to the embodiment of this disclosure, but can alternatively be another structure known to those skilled in the art, although the embodiment of this disclosure will not be limited thereto.

Of course, the respective switch transistors as referred to in the shift register above according to the embodiment of this disclosure can be Thin Film Transistors (TFT), or can be Metal Oxide Semiconductors (MOS); and the control electrodes of the respective switch transistors above are their gates, and the first electrodes and the second electrodes of the seven switch transistors above are fabricated in the same process, so their denominations can be interchanged, that is, they can be changed in denomination dependent upon their voltage directions. Stated otherwise, the first electrodes can be their sources, and the second electrodes can be their drains; or the first electrodes can be their drains, and the second electrodes can be their sources.

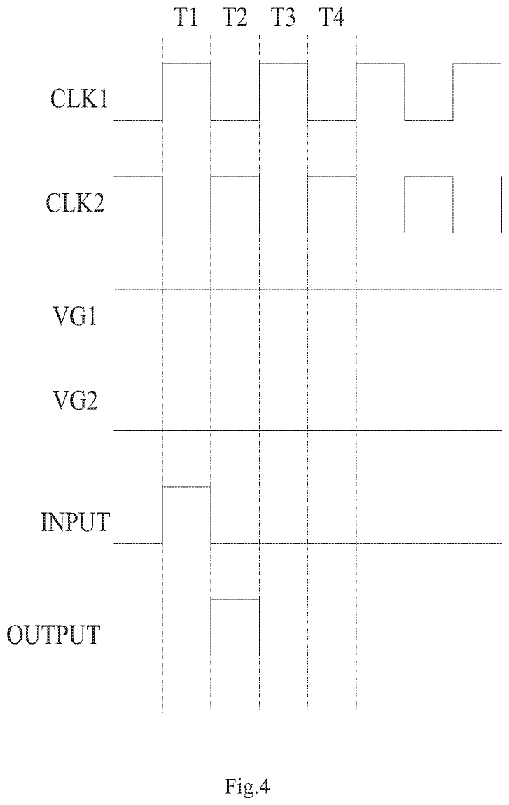

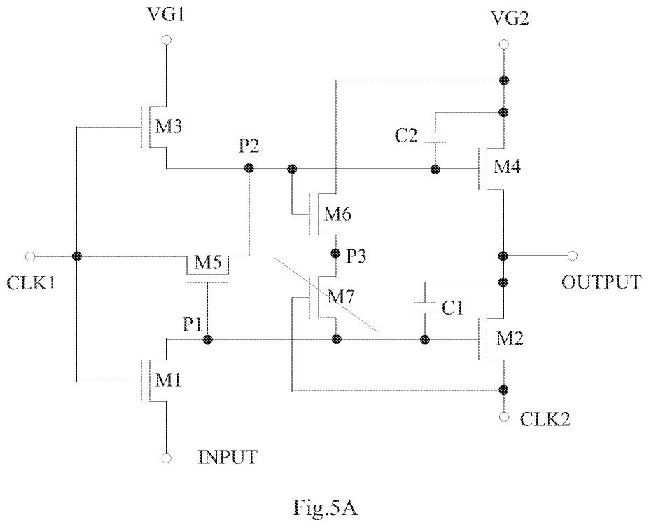

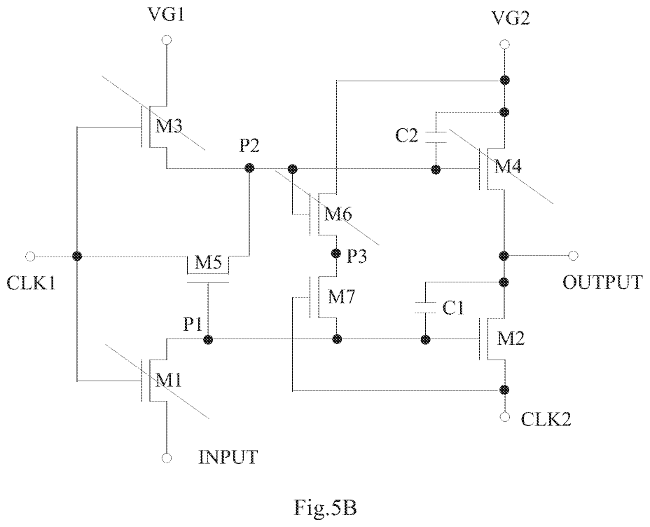

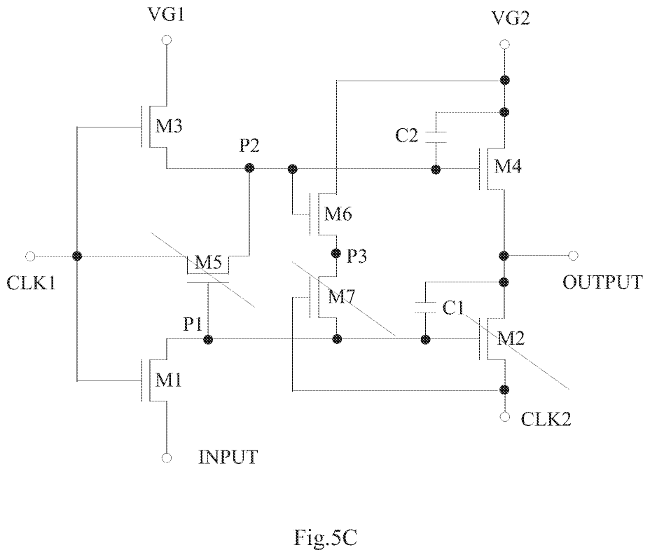

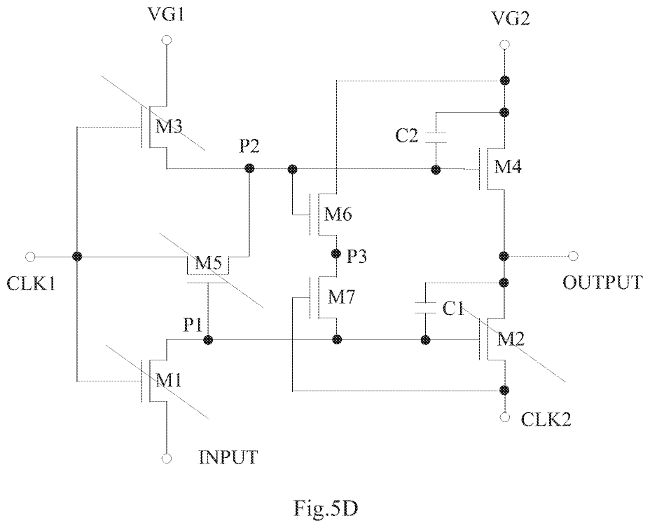

An operating process of the shift register above according to the embodiment of this disclosure will be described below in details with reference to the shift register as illustrated in FIG. 3a, and the input-output timing diagram as illustrated in FIG. 4 as well as the schematic diagrams of operating states of the respective switch transistors in respective periods of time as illustrated in FIG. 5a to FIG. 5d.

Optionally in the shift register as illustrated in FIG. 3a, the respective switch transistors are N-type switch transistors, a high-level signal is provided at the first reference signal terminal VG1, and a low-level signal is provided at the second reference signal terminal VG2, for example; there are four selected stages T1 to T4 in the input-output timing diagram as illustrated in FIG. 4; and 1 represents a high-level signal, and 0 represents a low-level signal in the following description.

In the T1 period of time, INPUT=1, CLK1=1, CLK2=0, VG1=1, and VG2=0. As illustrated in FIG. 5a, with INPUT=1 and CLK1=1, the first switch transistor M1 is switched on to output a high-level signal input at the signal input terminal INPUT to the first node P1, so that the level at the first node P1 is a high level: both the second switch transistor M2 and the fifth switch transistor M5 are switched on, so that the second switch transistor M2 outputs a low-level signal input at the second clock signal terminal CLK2 to the signal output terminal OUTPUT, and the fifth switch transistor M5 outputs a high-level signal input at the first clock signal terminal CLK1 to the second node P2; with CLK1=1, the third switch transistor M3 is also switched on to also output the high-level signal input at the first reference signal terminal VG1 to the second node P2; and both the third switch transistor M3 and the fifth switch transistor M5 maintain the level of the second node P2 at a high level, so that the fourth switch transistor M4 is switched on to output the low-level signal input at the second reference signal terminal VG2 to the signal output terminal OUTPUT, so the T1 period of time is a stage in which the shift register outputs a switch-off signal.

In the T2 period of time, INPUT=0, CLK1=0, CLK2=1, VG1=1, and VG2=0. As illustrated in FIG. 5b, the level at the first node P1 is maintained at a high level due to the bootstrap function of the first capacitor C1, so that both the second switch transistor M2 and the fifth switch transistor M5 are switched on throughout this period of time, so the fifth switch transistor M5 outputs a low-level signal input at the first clock signal terminal CLK1 to the second node P2, so that the level at the second node P2 is pulled down to a low level in this period of time; also with CLK1=0, the third switch transistor M3 is also switched off, so that the level at the second node P2 is stabilized at a low level, so the fourth switch transistor M4 is switched off; and furthermore the second switch transistor M2 outputs a high-level signal input at the second clock signal terminal CLK2 to the signal output terminal OUTPUT, so that a high-level signal is output at the signal output terminal OUTPUT to switch on all the switch transistors, connected on the N-th row of gate line corresponding to the shift register, in a display area of a display panel through the N-th row of gate line, and a data signal starts being written on a data line, so the T2 period of time is a stage in which the shift register outputs a switch-on signal.

In the T3 period of time, INPUT=0, CLK1=1, CLK2=0, VG1=1, and VG2=0. As illustrated in FIG. 5c, with CLK1=1, both the first switch transistor M1 and the third switch transistor M3 are switched on; also with INPUT=0, the first switch transistor M1 outputs a low-level signal input at the signal input terminal INPUT to the first node P1 to pull the level at the first node P1 down to a low level, so that both the second switch transistor M2 and the fifth switch transistor M5 are switched off; the third switch transistor M3 is switched on to output the high-level signal input at the first reference signal terminal VG1 to the second node p2 to pull the level at the second node P2 from a low level up to a high level, so that the fourth switch transistor M4 is switched on to output the low-level signal input at the second reference signal terminal VG2 to the signal output terminal OUTPUT, so a low-level signal is output at the signal output terminal OUTPUT, and the signal output terminal OUTPUT is reset, so the T3 period of time is a reset stage in which the shift register outputs a low-level signal.

In the T4 period of time, INPUT=0, CLK1=0, CLK2=1, VG1=1, and VG2=0. As illustrated in FIG. 5d, with CLK1=0, and the level at the first node P1 being maintained at a low level, the second switch transistor M2 and the fifth switch transistor M5 are still switched off: also the level at the second node P2 is maintained at a high level due to the bootstrap function of the second capacitor C2, so that both the fourth switch transistor M4 and the sixth switch transistor M6 are switched on, so the fourth switch transistor M4 outputs the low-level signal input at the second reference signal terminal VG2 to the signal output terminal OUTPUT, so that a low-level signal is output at the signal output terminal OUTPUT; also the sixth switch transistor M6 outputs the low-level signal input at the second reference signal terminal VG2 to the third node P3, so that the level at the third node P3 is a low level; and also with CLK2=1, the seventh switch transistor M7 is switched on to pass the low-level signal at the third node p3 to the first node P1, so that the level at the first node P1 is stabilized at a low level, and the second switch transistor M2 and the fifth switch transistor M5 are still switched off, thus avoiding a floating clock signal from interfering with the low-level signal output at the signal output terminal OUTPUT, so the T4 period of time is a stage in which the shift register outputs a switch-off signal.

Thereafter when the next T1 period of time occurs, that is, INPUT=1, CLK1=1, CLK2=0, VG1=1, and VG2=0, the process in the T1 period of time restarts, so the operating process in the periods of time T1 to T4 can be regarded as an operating cycle of the shift register in which the seven switch transistors and the two capacitors can operate in cooperation, and the shift register can operate normally using a smaller number of switch transistors and a simpler circuit structure; and also the third switch transitory M3 and the fourth switch transistor M4 can operate in cooperation so that the signal output terminal OUTPUT can be reset, so a reset circuit will not be arranged, thus simplifying the circuit structure, and facilitating a design of the display panel with a narrow bezel; and furthermore as can be intuitively apparent from FIG. 5a to FIG. 5d, the respective switch transistors can operate intermittently in an operating cycle to thereby avoid some switch transistor from operating for a long period of time, which would otherwise result in instable operation of the shift register.

FIG. 3b illustrates the shift register in which all of the switch transistors are P-type switch transistors, i.e., of the opposite transistor type to the corresponding switch transistors in the shift register as illustrated in FIG. 3a, so the levels of the respective signals in the input-output timing diagram corresponding to the shift register as illustrated in FIG. 3b are also opposite to the levels of the corresponding signals in the input-output timing diagram as illustrated in FIG. 4, so that the shift register as illustrated in FIG. 3b can operate normally. Accordingly reference can be made to the operating process of the shift register as illustrated in FIG. 3a for an operating process of the shift register as illustrated in FIG. 3b, so a repeated description thereof will be omitted here.

Based upon the same inventive idea, an embodiment of this disclosure further provides a gate integrated driver circuit, which can include a plurality of cascaded shift registers above according to the embodiment of this disclosure.

The signal input terminal of the first level of shift register is connected with a frame start signal terminal.

The signal output terminals of the respective other levels of shift registers than the last level of shift register are connected respectively with the signal input terminals of their immediately succeeding levels of shift registers.

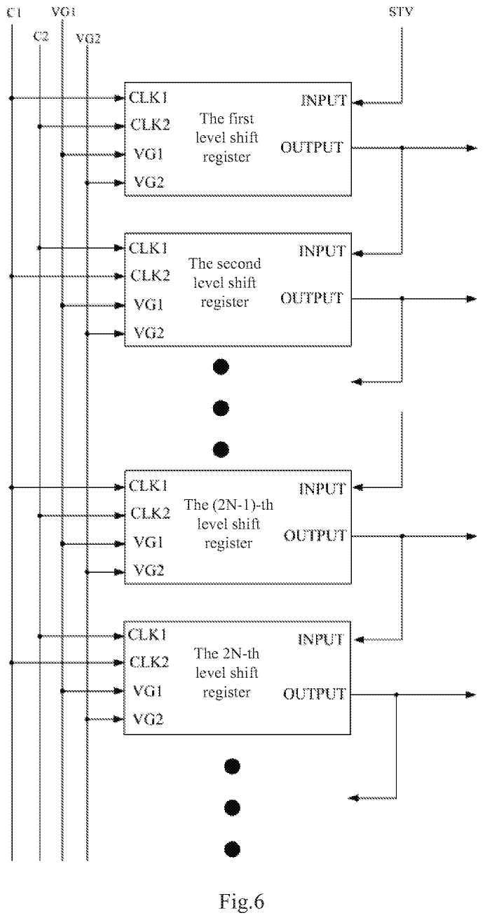

Optionally FIG. 6 illustrates only a part of the shift registers in the gate integrated driver circuit as the first level of shift register, the second of shift register, the (2N−1)th level of shift register, and the 2N-th level of shift register, where the signal input terminal INPUT of the first level of shift register is connected with the frame start signal terminal STV to have an frame start signal input thereto to start the shift registers in the gate integrated driver circuit, and a pulse signal output at the signal output terminal OUTPUT is output to the signal input terminal INPUT of the second of shift register as a signal to the signal input terminal INPUT of the second of shift register; and thereafter the signal output terminals OUTPUT of the respective other levels of shift registers than the last level of shift register are connected respectively with the signal input terminals INPUT of their immediately succeeding levels of shift registers to input their signals to the signal input terminals INPUT of their succeeding levels of shift registers, so that no reset signals will be output from the succeeding levels of shift registers to the preceding levels of shift registers, thus reducing the amount of wiring in the gate integrated driver circuit, and greatly simplifying the circuit structure so as to facilitate a design of a display device with a narrow bezel.

Furthermore in order to enable the gate integrated driver circuit to operate normally, as illustrated in FIG. 6, the first clock signal terminals CLK1 of the odd shift registers are connected with a first clock signal control line C1, and the second clock signal terminals CLK2 thereof are connected with a second clock signal control line C2, so that the odd shift registers can operate normally; and the first clock signal terminals CLK1 of the even shift registers are connected with the second clock signal control line C2, and the second clock signal terminals CLK2 thereof are connected with the first clock signal control line C1, so that the even shift registers can operate normally.

Optionally a structure of each shift register in the gate integrated driver circuit above according to the embodiment of this disclosure is functionally and structurally the same as the shift register above according to the embodiment of this disclosure, so a repeated description thereof will be omitted here.

Based upon the same inventive idea, an embodiment of this disclosure further provides a display device, which can include the gate integrated driver circuit above according to the embodiment of this disclosure. The display device can be a mobile phone, a tablet computer, a TV set, a monitor, a notebook computer, a digital photo frame, a navigator, or any other product or component with a display function; and reference can be made to the description of the gate integrated driver circuit above according to the embodiment of this disclosure for an optional implementation of the display device, so a repeated description thereof will be omitted here.

Based upon the same inventive idea, an embodiment of this disclosure further provides a method for driving the shift register above according to the embodiment of this disclosure, where the method can include following steps.

Providing, by the first clock signal terminal, the input control circuit, the pull-up control circuit, and the first pull-down control circuit respectively with a first level signal, and providing, by the signal input terminal, the input control circuit with the first level signal, so that a second level signal at the second clock signal terminal and the second level signal at the second reference signal terminal are output to the signal output terminal.

Providing, by the first clock signal terminal, the input control circuit, the pull-up control circuit, and the first pull-down control circuit respectively with the second level signal, and providing, by the signal input terminal, the input control circuit with the second level signal, so that the first level signal at the second clock signal terminal is output to the signal output terminal.

Providing, by the first clock signal terminal, the input control circuit, the pull-up control circuit, and the first pull-down control circuit respectively with the first level signal, and providing, by the signal input terminal, the input control circuit with the second level signal, so that the second level signal at the second reference signal terminal is output to the signal output terminal.

Providing, by the first clock signal terminal, the input control circuit, the pull-up control circuit, and the first pull-down control circuit respectively with the second level signal, and providing, by the signal input terminal, the input control circuit with the second level signal, so that the second level signal at the second reference signal terminal is output to the signal output terminal.

In an optional implementation, in the driving method above according to the embodiment of this disclosure, the first level signal refers to a level signal which can switch on corresponding transistors, and the second level signal refers to a level signal which can switch off the corresponding transistors. Furthermore in an optional implementation, there may be different real voltage values of the first level signal corresponding to the clock signal terminal, and the first level signal corresponding to the signal input terminal, and their real voltage values shall be determined dependent upon a real application context, although the embodiment of this disclosure will not be limited thereto.

In an optional implementation, the first level signal can be a high-level signal, and correspondingly the second level signal can be a low-level signal; or the first level signal can be a low-level signal, and correspondingly the second level signal can be a high-level signal. The first level signal and the second level signal can be set optionally dependent upon whether the transistors are N-type transistors or P-type transistors, although the embodiment of this disclosure will not be limited thereto. Optionally FIG. 4 illustrates a circuit timing diagram when the transistors in the shift register are N-type transistors, where the first level signal is a high-level signal, and the second level signal is a low-level signal. Of course, when the transistors in the shift register are P-type transistors, the first level-signal can be a low-level signal, and the second level signal can be a high-level signal.

Optionally referring to the shift register as illustrated in FIG. 3a, and the input-output timing diagram as illustrated in FIG. 4, in the first period of time, the input control circuit 101 transmits the signal input at the signal input terminal INPUT to the first node P1 under the control of the first level signal input at the first clock signal terminal CLK1; the first output control circuit 102 transmits the clock signal input at the second clock signal terminal CLK2 to the signal output terminal OUTPUT under the control of the first node P1; the first pull-down control circuit 104 transmits the clock signal input at the first clock signal terminal CLK1 to the second node P2 under the control of the first node P1; the pull-up control circuit 103 transmits the first reference signal input at the first reference signal terminal VG1 to the second node P2 under the control of the first level signal input at the first clock signal terminal CLK1; and the second output control circuit 105 transmits the first reference signal input at the first reference signal terminal VG1 to the signal output terminal OUTPUT under the control of the second node P2.

In the second period of time, the first pull-down control circuit 104 transmits the second level signal input at the first clock signal terminal CLK1 to the second node P2 under the control of the first node P1; and the first output control circuit 102 transmits the first level signal input at the second clock signal terminal CLK2 to the signal output terminal OUTPUT under the control of the first node P1.

In the third period of time, the input control circuit 101 transmits the signal input at the signal input terminal INPUT to the first node P1 under the control of the first level signal input at the first clock signal terminal CLK1; the pull-up control circuit 103 transmits the first reference signal input at the first reference signal terminal VG1 to the second node P2 under the control of the first level signal input at the first clock signal terminal CLK1: and the second output control circuit 105 transmits the second reference signal input at the second reference signal terminal VG2 to the signal output terminal OUTPUT under the control of the second node P2.

In the fourth period of time, the second output control circuit 105 transmits the second reference signal input at the second reference signal terminal VG2 to the signal output terminal OUTPUT under the control of the second node P2.

In an optional implementation, in the driving method above according to the embodiment of this disclosure, when the first clock signal terminal provides the input control circuit, the pull-up control circuit, and the first pull-down control circuit respectively with the second level signal, and the signal input terminal provides the input control circuit with the second level signal, so that the second level signal terminal at the second reference signal terminal is output to the signal output terminal, the method can further include following step.

Providing, by the second clock signal terminal, the second pull-down control circuit with the first level signal, so that the second reference signal at the second reference terminal is output to the first node. Optionally referring to the shift register as illustrated in FIG. 3a, and the input-output timing diagram as illustrated in FIG. 4, the second pull-down control circuit 106 transmits the second reference signal input at the second reference signal terminal VG2 to the first node P1 under the joint control of the second node P2 and the first level signal input at the second clock signal terminal CLK2.

In the shift register, the method for driving the same, the gate integrated driver circuit, and the display device according to the embodiments of this disclosure, the shift register includes: an input control circuit configured to output a signal input at a signal input terminal to a first node under the control of a first clock signal terminal; a first output control circuit configured to output a clock signal input at a second clock signal terminal to a signal output terminal under the control of the first node; a pull-up control circuit configured to output a first reference signal input at a first reference signal terminal to a second node under the control of the first clock signal terminal; a pull-down control circuit configured to output a clock signal input at the first clock signal terminal to the second node under the control of the first node; and a second output control circuit configured to output a second reference signal input at a second reference signal terminal to the signal output terminal under the control of the second node; and the first reference signal terminal and the second reference signal terminal are configured respectively to provide a high-level signal and a low-level signal, so the first output control circuit and the second output control circuit can be arranged respectively to provide a high-level signal and a low-level signal, and to output a stable low-level signal without any interference from another signal. Also the first output control circuit and the second output control circuit can operate intermittently to thereby extend the service lifetime of the shift register.

Furthermore the pull-up control circuit and the second output control circuit can operate in cooperation to thereby function as a reset circuit for resetting the signal output terminal, so a reset circuit can be dispensed with. Moreover in the gate integrated driver circuit including a plurality of concentrated shift registers, no reset signals will be output from the succeeding levels of shift registers to the preceding levels of shift registers, thus reducing the amount of wiring in the gate integrated driver circuit, and greatly simplifying the circuit structure so as to facilitate a design of the display device with a narrow bezel.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A shift register, comprising:
an input control circuit, connected to a signal input terminal, a first clock signal terminal and a first node respectively, configured to output a signal input at the signal input terminal to the first node under a control of the first clock signal terminal;
a first output control circuit, connected to the first node, a second clock signal terminal and a signal output terminal respectively, configured to output a clock signal input at the second clock signal terminal to the signal output terminal under a control of the first node;
a pull-up control circuit, connected to the first clock signal terminal, a second node and a first reference signal terminal respectively, configured to output a first reference signal input at the first reference signal terminal to the second node under the control of the first clock signal terminal;
a pull-down control circuit, connected to the first node, the first clock signal terminal and the second node respectively, configured to output a clock signal input at the first clock signal terminal to the second node under the control of the first node; and
a second output control circuit, connected to the second node, a second reference signal terminal and the signal output terminal respectively, configured to output a second reference signal input at the second reference signal terminal to the signal output terminal under a control of the second node.

2. The shift register according to claim 1, wherein the input control circuit comprises a first switch transistor, wherein:
the first switch transistor comprises a control electrode connected with the first clock signal terminal, a first electrode connected with the signal input terminal and a second electrode connected with the first node.

3. The shift register according to claim 1, wherein the first output control circuit comprises a second switch transistor and a first capacitor, wherein:
the second switch transistor comprises a control electrode connected with the first node, a first electrode connected with the second clock signal terminal and a second electrode connected with the signal output terminal; and
the first capacitor is connected between the first node and the signal output terminal.

4. The shift register according to claim 1, wherein the pull-up control circuit comprises a third switch transistor, wherein:
the third switch transistor comprises a control electrode connected with the first clock signal terminal, a first electrode connected with the first reference signal terminal and a second electrode connected with the second node.

5. The shift register according to claim 1, wherein the second output control circuit comprises a fourth switch transistor and a second capacitor, wherein:
the fourth switch transistor comprises a control electrode connected with the second node, a first electrode connected with the second reference signal terminal and a second electrode connected with the signal output terminal; and
the second capacitor is connected between the second node and the second reference signal terminal.

6. The shift register according to claim 1, wherein the first pull-down control circuit comprises a fifth switch transistor, wherein:
the fifth switch transistor comprises a control electrode connected with the first node, a first electrode connected with the first clock signal terminal and a second electrode connected with the second node.

7. The shift register according to claim 1, further comprises a second pull-down control circuit, connected to the first node, the second node, the second clock signal terminal and the second reference signal terminal respectively, configured to output the second reference signal input at the second reference signal terminal to the first node under a joint control of the second node and the clock signal input at the second clock signal terminal.

8. The shift register according to claim 7, wherein the second pull-down control circuit comprises a sixth switch transistor and a seventh switch transistor, wherein:
the sixth switch transistor comprises a control electrode connected with the second node, a first electrode connected with the second reference signal terminal and a second electrode connected with a third node; and
the seventh switch transistor comprises a control electrode connected with the second clock signal terminal, a first electrode connected with the third node, and a second electrode connected with the first node.

9. A gate integrated driver circuit, comprising a plurality of cascaded shift registers according to claim 1, wherein:
the signal input terminal of a first level shift register of the plurality of cascaded shift registers is connected with a frame start signal terminal; and
the signal output terminal of each of other level shift registers of the plurality of cascaded shift registers than a last level shift register of the plurality of cascaded shift registers is connected with a signal input terminal of an immediately succeeding level shift register of the each of other shift registers.

10. A display device, comprising the gate integrated driver circuit according to claim 9.

11. A method for driving the shift register according to claim 1, the method comprising:
providing, by the first clock signal terminal, the input control circuit, the pull-up control circuit, and the first pull-down control circuit respectively with a first level signal, and providing, by the signal input terminal, the input control circuit with the first level signal, so that a second level signal at the second clock signal terminal and the second reference signal at the second reference signal terminal are output to the signal output terminal;
providing, by the first clock signal terminal, the input control circuit, the pull-up control circuit, and the first pull-down control circuit respectively with the second level signal, and providing, by the signal input terminal, the input control circuit with the second level signal, so that the first level signal at the second clock signal terminal is output to the signal output terminal;
providing, by the first clock signal terminal, the input control circuit, the pull-up control circuit, and the first pull-down control circuit respectively with the first level signal, and providing, by the signal input terminal, the input control circuit with the second level signal, so that the second reference signal at the second reference signal terminal is output to the signal output terminal; and
providing, by the first clock signal terminal, the input control circuit, the pull-up control circuit, and the first pull-down control circuit respectively with the second level signal, and providing, by the signal input terminal, the input control circuit with the second level signal, so that the second reference signal at the second reference signal terminal is output to the signal output terminal.

12. The driving method according to claim 11, wherein in response to that the first clock signal terminal provides the input control circuit, the pull-up control circuit, and the first pull-down control circuit respectively with the second level signal, and the signal input terminal provides the input control circuit with the second level signal, so that the second level signal terminal at the second reference signal terminal is output to the signal output terminal, the method further comprises:
providing, by the second clock signal terminal, the second pull-down control circuit with the first level signal, so that the second reference signal at the second reference terminal is output to the first node.
